(19) United States
(12) Patent Application Publication
(10) Pub. No.: US 2018/0136271 A1
(43) Pub. Date: May 17, 2018

(54) CAPACITIVE SENSOR WITH SELF-TEST FEATURE

(71) Applicant: TOUCHSENSOR TECHNOLOGIES, LLC, WHEATON, IL (US)

(72) Inventor: Randall Philipson, Wheaton, IL (US)

(21) Appl. No.: 15/810,696

(22) Filed: Nov. 13, 2017

Related U.S. Application Data
(60) Provisional application No. 62/421,913, filed on Nov. 14, 2016.
(60) Provisional application No. 62/444,925, filed on Jan. 11, 2017.

(51) Int. Cl. G01R 31/28; G06F 3/044; G01R 35/00

(52) U.S. Cl. CPC G01R 31/2829; G01R 35/007; G06F 3/044

(57) ABSTRACT

A capacitive sensor includes sensor electrode structure and a controller operating the sensor. The sensor also includes test drive electrode structure or a reference capacitor, the controller operating the test drive electrode structure or the reference capacitor to test operability of the sensor.

### CROSS-REFERENCE TO RELATED APPLICATIONS

This application claims benefit under 35 U.S.C. § 119 U.S. Provisional Patent Application Nos. 62/421,913, filed on Nov. 14, 2016, and 62/444,925, filed on Jan. 11, 2017, and incorporates by reference the disclosures thereof in their entireties.

### BACKGROUND AND SUMMARY OF THE DISCLOSURE

Capacitive sensors are known in the art. It would be desirable to provide means for testing such sensors in place to confirm their operability.

### BRIEF DESCRIPTION OF THE DRAWINGS

FIG. 1 is a diagram of a stack-up of layers of a capacitive sensor including first and second dielectric substrates and first and second conductive layers associated with the first and second substrates according to the present disclosure;

FIG. 2 is a diagram of a differential sensing electrode structure and test electrode structure according to the present disclosure;

FIG. 3 is a diagram of an alternative differential sensing electrode structure and test electrode structure according to the present disclosure;

FIG. 4 is a diagram of another alternative differential sensing electrode structure and test electrode structure according to the present disclosure; and

FIG. 5 is diagram of a sensing electrode structure and test electrode structure of a capacitive sensor configured for a self-capacitance mode of operation.

### DETAILED DESCRIPTION OF THE DRAWINGS

The drawings show various illustrative embodiments of a capacitive sensor system 10 having integral test structure.

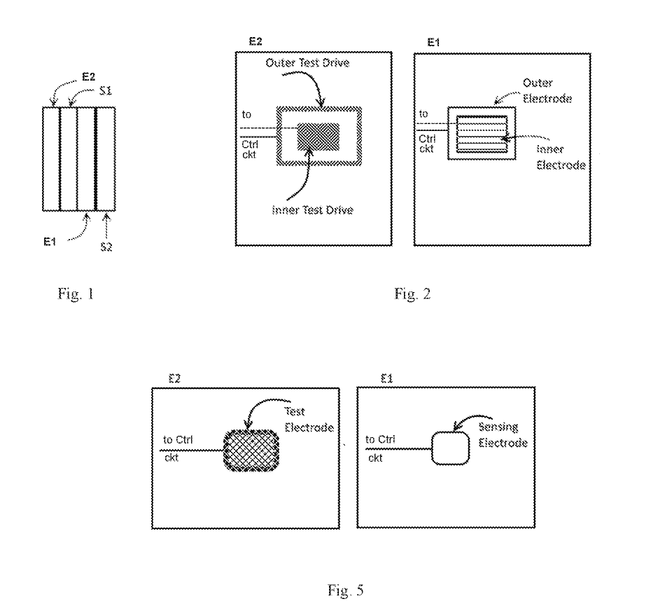

FIG. 1 shows a physical stack up of layers of the capacitive sensor system 10. More specifically, FIG. 1 shows a first dielectric substrate S1, a first electrically conductive layer E1 disposed on a first side of the first substrate S1, a second electrically conductive layer E2 disposed on a second side of the first substrate S1, and a second dielectric substrate S2 disposed on a side of the first conductive layer E1 opposite the first substrate S1.

The first substrate S1 may be any rigid or flexible substrate suitable for use as an electric circuit carrier. For example, the first substrate could be a piece of FR-4 PCB substrate material or a flexible polyester circuit carrier.

The first and second conductive layers E1, E2 could be any material suitable for use as an electrical circuit trace and/or sensing electrode of a capacitive sensor. For example, the first and second conductive layers E1, E2 could be made of copper, indium tin oxide (ITO), or another suitable opaque or transparent conductive material. Either or both of the first and second conductive layers E1, E2 could comprise more than one layer of conductive material. For example, either or both of the first and second conductive layers E1, E2 could include a layer of copper material and a layer of ITO, multiple layers of a single conductive material, or any other suitable combination of materials.

The first conductive layer E1 may define one or more sensing electrodes and one or more electrical traces electrically coupling the one or more sensing electrodes to other circuit components (not shown). For example, the circuit traces could couple the sensing electrodes to an active component proximate the sensing electrode (for example, as disclosed in U.S. Pat. Nos. 5,594,222, 6,310,611, and 6,320,282, the disclosures of which are incorporated herein by reference in their entireties), and/or to a controller (not shown) configured to provide signals to the sensing electrodes and to receive and process signals from the sensing electrodes.

The second conductive layer E2 may define one or more test drive electrodes and one or more electrical traces electrically coupling the one or more sensing electrodes to other circuit components. For example, the circuit traces could couple the one or more test drive electrodes to a controller configured to provide signals to the test drive electrodes or to a switch or other component. The one or more test drive electrodes may correspond to and be at least partially in registration with the one or more sensing electrodes defined by the first conductive layer E1.

The second substrate S2 could be embodied as any suitable material and/or structure. For example, the second substrate S2 could be a wall of a vessel containing a liquid to be sensed, the wall or at least relevant portions thereof being made of a dielectric material. In another embodiment, the second substrate S2 could be a user touch panel of a user interface, the user interface comprising sensors including sensing electrodes, for example, as described above, wherein the sensors are configured to respond to touch of or approach to the panel by a user or other stimulus.

FIG. 2 shows an embodiment wherein the first conductive layer E1 defines a sensing electrode structure configured for differential sensing (for example, as disclosed in U.S. Pat. No. 6,310,611, with or without the active component proximate the sensing electrodes as described therein) and the second conductive layer E2 defines a corresponding test electrode structure. More specifically, the first conductive layer E1 defines a sensing electrode structure comprising a first or inner sensing electrode and a second or outer sensing electrode. Each of the first and second sensing electrodes is electrically coupled to the controller (not shown). Similarly, the second conductive layer E2 defines a corresponding test electrode structure comprising a first or inner test drive electrode and second test drive electrode. Each of the first and second test drive electrodes is electrically coupled to the controller (not shown). The first sensing electrode overlies or is in registration with the first test drive electrode, and the second sensing electrode overlies or is in registration with the second test drive electrode.

Under normal, non-test, operating conditions, the sensing electrodes operate conventionally, for example, as set forth in U.S. Pat. No. 6,310,611 (with or without the active component proximate the sensing electrodes as described therein), and the first and second (inner and outer) test drive electrodes are at a floating potential.

The operability of the sensor, that is, the ability of an unactuated sensor to respond to touch or proximity to the first sensing electrode and the ability of an actuated sensor to respond to touch or proximity to the second sensing electrode, may be tested as follows.

With the sensor not actuated, the first test drive electrode is connected to a ground potential and the second test drive electrode is left floating. This simulates touch or proximity of a user or liquid to the first sensing electrode by substantially sinking capacitance from the first sensing electrode to ground, but not substantially sinking capacitance from the second sensing electrode. Consequent actuation of the sensor indicates that the sensor should become actuated in response to touch of or proximity to the first sensing electrode as intended. Failure of the sensor to actuate under these test circumstances indicates improper operation of the sensor.

With the sensor actuated (whether by the foregoing grounding of the test drive electrode or by touch of or proximity to the first sensing electrode by a user or other stimulus), the second test drive electrode is connected to a ground potential. This simulates touch or proximity of a user or liquid to the second sensing electrode (or removal of the stimulus touching or proximate the first sensing electrode) by substantially sinking capacitance from the second sensing electrode to ground, regardless of any sinking of capacitance from the first sensing electrode. Consequent de-actuation of the sensor indicates that the sensor should respond to touch of or proximity to the second sensing electrode as intended. Failure of the sensor to de-actuate under these test circumstances indicates improper operation of the sensor.

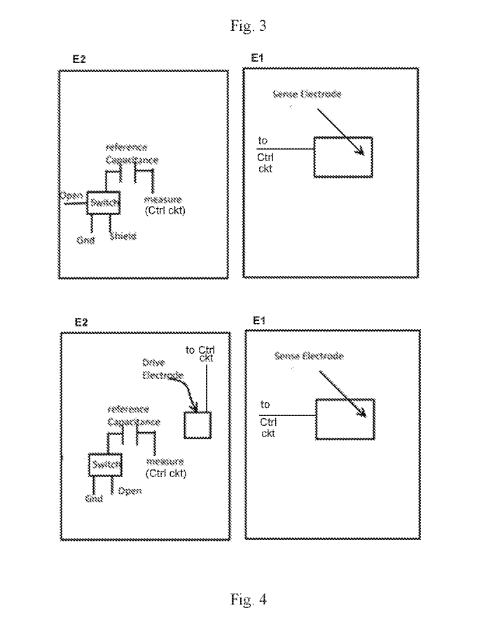

FIG. 3 shows an alternative differential sensing embodiment wherein the first conductive layer E1 defines a sense electrode. Alternatively, the second conductive layer E2 could define the sense electrode. The sense electrode is electrically coupled to a controller (not shown) that provides signals to and detects signals from the sense electrode in a conventional manner.

A reference capacitor is disposed on the second conductive layer E2 sufficiently near to the sense electrode to provide temperature compensation, as would be understood by one skilled in the art. A first plate of the reference capacitor is electrically coupled to the controller (not shown). A second plate of the reference capacitor is electrically coupled to a multi-position switch (which may be embodied as an analogous switching circuit). The switch is operable to electrically couple the second plate of the reference capacitor to a ground, to a floating potential, or to the control circuit wherein the control circuit drives the second plate of the reference capacitor as a driven shield. Coupling to the floating potential may be accomplished by simply leaving the switch in an open position or by placing the switch in a position corresponding to an unterminated pin or lead.

Under normal, non-test conditions, the second plate of the reference capacitor is set at a floating potential, for example, by leaving the switch in an open position. Also, the first plate of the reference capacitor is coupled to the controller, as discussed above. The controller excites the sense electrode and the first plate of the reference capacitor and analyzes signals received from the sense electrode and the first plate of the reference capacitor in a conventional manner.

The operability of the sensor may be tested as follows.

With the sensor not actuated, the switch may be set to couple the second plate of the capacitor to the control circuit so that the control circuit energizes the second plate of the reference capacitor as a driven shield. So coupled, and with the second plate of the reference capacitor energized as a driven shield, the capacitance of the reference capacitor is greatly decreased compared to its capacitance with the second plate at floating potential, and thus greatly decreased relative to the capacitance of the sense electrode, thereby causing the sensor to actuate. Consequent actuation of the sensor indicates that the sensor should become actuated in response to touch of or proximity to the sense electrode by a stimulus as intended. Failure of the sensor to actuate under these test circumstances indicates improper operation of the sensor.

With the sensor actuated, the switch may be set to couple the second plate of the reference capacitor to ground. So coupled, the capacitance of the reference capacitor is greatly increased compared to its capacitance with the second plate at floating potential, and thus greatly increased relative to the capacitance of the sense electrode, thereby causing the sensor to de-actuate. Consequent de-actuation of the sensor indicates that the sensor should respond to removal of a stimulus in touch or proximity to the second sensing electrode as intended. Failure of the sensor to de-actuate under these test circumstances indicates improper operation of the sensor.

FIG. 4 shows another alternative differential sensing embodiment wherein the first conductive layer E1 defines a sense electrode and the second conductive layer E2 defines a corresponding drive electrode at least partially in registration with the sense electrode. The sense electrode and drive electrode are electrically coupled to a controller that provides signals to the drive electrode and detects signals from the sense electrode in a conventional manner.

A reference capacitor is disposed on the second circuit layer E2 sufficiently near to the drive and sense electrodes to provide temperature compensation, as would be understood by one skilled in the art. A first plate of the reference capacitor is electrically coupled to the controller (not shown). A second plate of the reference capacitor is electrically coupled to a multi-position switch (which may be embodied as an analogous switching circuit). The switch is operable to electrically couple the second terminal of the reference capacitor to a ground or to a floating potential. Coupling to the floating potential may be accomplished by simply leaving the switch in an open position or by placing the switch in a position corresponding to an unterminated pin or lead.

Under normal, non-test conditions, the second plate of the reference capacitor is set to a floating potential, for example, by leaving the switch in an open position. Also, the first plate of the reference capacitor is coupled to the controller, as discussed above. The controller excites the drive electrode and the first plate of the reference capacitor and analyzes signals received from the sense electrode and the first plate of the reference capacitor in a conventional manner.

The operability of the sensor may be tested as follows.

With the sensor not actuated, the drive electrode may be coupled to ground using a suitable switch (which may be embodied as an analogous switching circuit) (not shown). With the drive electrode so coupled to ground and the second plate of the reference capacitor coupled to a floating potential, the capacitance of the reference capacitor is greatly decreased compared to its capacitance with the drive electrode coupled to the controller, and thus greatly decreased relative to the capacitance at the sense electrode, thereby causing the sensor to actuate. Consequent actuation of the sensor indicates that the sensor should respond to touch of or proximity to the sense electrode as intended. Failure of the sensor to actuate under these test circumstances indicates improper operation of the sensor.

With the sensor actuated, the switch may be set in the second position, thereby coupling the second plate of the capacitor to ground potential. With the second plate of the capacitor so coupled, the capacitance of the reference capacitor is greatly increased compared to its capacitance with the second plate at floating potential, and thus greatly increased relative to the capacitance at the sensing electrode. This change in relative capacitance should cause the sensor to de-actuate. Consequent de-actuation of the sensor indicates that the sensor should become actuated in response to touch of or proximity to the sensing electrode as intended. Failure of the sensor to de-actuate under these test circumstances indicates improper operation of the sensor.

FIG. 5 shows an embodiment directed to a sensor having a single sensing electrode and a operating in a self-capacitance mode of operation. In the FIG. 5 embodiment, the first conductive layer E1 defines a sensor having a single sensing electrode, and the second conductive layer E2 defines a test drive electrode corresponding to and at least partially in registration with the sensing electrode. In this embodiment, the test drive electrode is normally at a floating potential. Operability of the sensor may be tested as follows.

With the sensor not actuated, the test drive electrode may be connected to a ground potential. This simulates touch or proximity of a user or liquid to the sensing electrode by sinking capacitance from the sensing electrode to ground. Consequent actuation of the sensor indicates that the sensor should respond to touch of or proximity to the first sensing electrode as intended. Failure of the sensor to actuate under these test circumstances indicates improper operation of the sensor.

With the sensor actuated, the test drive electrode may be energized as a driven shield. This simulates absence or removal of touch or proximity of a user or liquid to the sensing electrode by adding capacitance thereto. Consequent de-actuation of the sensor indicates that the sensor should respond to removal of a touch or proximity to the sensing electrode as intended. Failure of the sensor to de-actuate under these test circumstances indicates improper operation of the sensor.

In the FIG. 5 embodiment, the sensing electrode could be disposed on the second conductive layer E2, and the test drive electrode could be disposed on the first conductive layer E1. So configured, the test drive electrode could be grounded to test actuation of the sensor, but it could not be energized as a driven shield to test de-actuation of the sensor.

1. A capacitive sensor comprising:
a first dielectric substrate having a first side and a second side;
a sensor electrode structure having a first sensing electrode disposed on the first side of the dielectric substrate; and
a controller coupled to the first sensing electrode, the controller configured to:
selectively energize the first sensing electrode, selectively detect capacitance at the first sensing electrode, and deem the sensor to be actuated or not actuated based on the capacitance detected at the first sensing electrode;
selectively simulate actuation of the sensor while the sensor is not actuated; and
selectively simulate deactivation of the sensor while the sensor is actuated or while the controller is simulating actuation of the sensor.

2. The sensor of claim 1 further comprising:
a test drive electrode structure disposed on the second side of the first dielectric substrate, the test drive electrode structure comprising a first test drive electrode and a second test drive electrode;
the capacitive sensor electrode structure further comprising a second sensing electrode disposed on the first side of the first dielectric substrate, the first sensing electrode at least partially overlying and in registration with the first test drive electrode, and the second sensing electrode at least partially overlying and in registration with the second test drive electrode; and
the controller further coupled to the second sensing electrode and to the first and second test drive electrodes;
the controller further configured to:
selectively energize one or both of the first sensor electrode and the second sensor electrode, selectively detect capacitance at one or both of the first sensor electrode and the second sensor electrode, and deem the sensor to be actuated or not actuated based on the capacitance detected at the first sensing electrode;
selectively simulate actuation of the sensor while the sensor is not actuated by coupling the first test drive electrode to a ground potential and holding the second test drive electrode at a floating potential; and
selectively simulate deactivation of the sensor while the sensor is actuated or while the controller is simulating actuation of the sensor by coupling both the first test drive electrode and the second test drive electrode to the ground potential.

3. The sensor of claim 2 wherein the controller is configured to deem the sensor to actuate properly if the controller deems the sensor to actuate while not actuated in response to the grounding of the first test drive electrode.

4. The sensor of claim 2 wherein the controller is configured to deem the sensor to not actuate properly if the controller deems the sensor to not actuate while not actuated in response to the grounding of the first test drive electrode.

5. The sensor of claim 2 wherein the controller is configured to deem the sensor to deactuate properly if the controller deems the sensor to deactuate when actuated in response to the grounding of the first test drive electrode and the second test drive electrode.

6. The sensor of claim 2 wherein the controller is configured to deem the sensor to not deactuate properly if the controller deems the sensor to not deactuate while actuated in response to the grounding of the first test drive electrode and the second test drive electrode.

7. The sensor of claim 2 wherein the controller is configured to deem the sensor to operate properly if the controller deems the sensor to actuate while not actuated in response to the grounding of the first test drive electrode, and if the controller deems the sensor to deactuate while actuated in response to the grounding of the first test drive electrode and the second test drive electrode.

8. The sensor of claim 2 wherein the controller is configured to deem the sensor to not operate properly if the controller deems the sensor to actuate while not actuated in response to the grounding of the first test drive electrode, and if the controller deems the sensor to deactuate while actuated in response to the grounding of the first test drive electrode and the second test drive electrode.

9. The sensor of claim 1 further comprising:
a reference capacitor proximate the first sensing electrode, the reference capacitor having a first plate and a second plate; and
a switch operable to selectively couple the second plate of the reference capacitor to ground, to a floating potential, or to the controller;
the controller further coupled to the capacitive sensor and to the first plate of the reference capacitor, the controller further configured to:
selectively energize the first sensor electrode, selectively detect capacitance at the first sensor electrode, and deem the sensor to be actuated or not actuated based on the capacitance detected at the first sensing electrode when the switch is configured to couple the second plate of the capacitor to the floating potential;
selectively energize the first plate of the reference capacitor and selectively detect the capacitance at the first plate of the reference capacitor;
selectively energize the second plate of the reference capacitor as a driven shield;
deem the sensor to actuate properly when, with the sensor not actuated and with the controller coupled to the second plate of the reference capacitor and energizing the second plate of the reference capacitor as a driven shield, the controller deems the capacitance of the reference capacitor to differ by a first predetermined value from the capacitance of the reference capacitor when the switch is configured to couple the second plate of the reference capacitor to the floating potential; and
deem the sensor to deactuate properly when, with the sensor actuated the sensor actuated and with the switch configured to couple the second plate of the reference capacitor to ground, the controller deems the capacitance of the reference capacitor to differ by a second predetermined value from the capacitance of the reference capacitor when the switch is configured to couple the second plate of the reference capacitor to the floating potential.

10. The apparatus of claim 9 wherein the first predetermined value is lower than the capacitance of the reference capacitor when the switch is configured to couple the second plate of the reference capacitor to the floating potential and the second predetermined value is greater than the capacitance of the reference capacitor when the switch is configured to couple the second plate of the reference capacitor to the floating potential.

11. The sensor of claim 1 further comprising:
a test drive electrode disposed on the second side of the first dielectric substrate, the test drive electrode at least partially overlying and in registration with the first sensing electrode; and
the controller further coupled to the test drive electrode;
the controller further configured to:
selectively energize the first sensing electrode, selectively detect capacitance at the first sensing electrode, and deem the sensor to be actuated or not actuated based on the capacitance detected at the first sensing electrode when the test drive electrode is at a floating potential,
selectively simulate actuation of the sensor while the sensor is not actuated by coupling the test drive electrode to a ground potential; and
selectively simulate deactivation of the sensor while the sensor is actuated or while the controller is simulating actuation of the sensor by energizing the test drive electrode as a driven shield.

12. A capacitive sensor comprising:
a first dielectric substrate having a first side and a second side;
a sensor electrode structure having a sense electrode disposed on the first side of the dielectric substrate and a drive electrode on the second side of the dielectric substrate, the drive electrode at least partially overlying and in registration with the sense electrode;
a reference capacitor proximate the sense electrode, the reference capacitor having a first plate and a second plate;
a first switch operable to selectively couple the second plate of the reference capacitor to ground or to a floating potential;
a second switch operable to selectively couple the sense electrode to ground; and
a controller coupled to the sense electrode and the drive electrode, the controller configured to:
with the first switch configured to couple the second plate of the reference capacitor to the floating potential, and with the second switch not configured to couple the sense electrode to ground, operate the capacitive sensor by selectively energizing the drive electrode, selectively detect capacitance at the sense electrode, and deem the sensor to be actuated or not actuated based on the capacitance detected at the sense electrode;
operate the reference capacitor by selectively energizing the first plate of the reference capacitor and selectively detecting the capacitance at the first plate of the reference capacitor;
deem the sensor to actuate properly when, with the sensor not actuated, with the first switch configured to couple the second plate of the reference capacitor to the floating potential and the second switch configured to couple the sense electrode to ground, the controller deems the capacitance of the reference capacitor to differ by a first predetermined value from the capacitance of the reference capacitor when the switch is configured to couple the second plate of the reference capacitor to the floating potential; and
deem the sensor to deactuate properly when, with the sensor actuated, the first switch configured to couple the second plate of the reference capacitor to ground, and the second switch configured to couple the sense electrode to ground, the controller deems the capacitance of the reference capacitor to differ by a second predetermined value from the capacitance of the reference capacitor when the switch is configured to couple the second plate of the reference capacitor to the floating potential.
